(19) United States
(12) Patent Application Publication
(10) Pub. No.: US 2023/0176105 A1
(43) Pub. Date: Jun. 8, 2023

(54) INSULATION DEFECT DETECTION METHOD AND DETECTION SYSTEM FOR MAGNET WIRE COATING, MANUFACTURING METHOD FOR ELECTRIC MACHINE, AND ELECTRIC MACHINE

(71) Applicant: Mitsubishi Electriic Corporation, Chiyoda-ku, Tokyo (JP)

(72) Inventors: Teiji TAKAHASHI, Tokyo (JP); Takahiro MISAWA, Tokyo (JP); Xutao LI, Tokyo (JP)

(73) Assignee: Mitsubishi Electriic Corporation, Chiyoda-ku, Tokyo (JP)

(21) Appl. No.: 17/997,848

(22) PCT Filed: Jan. 20, 2021
(86) PCT No.: PCT/JP2021/001763

§ 371 Date: Nov. 3, 2022

(30) Foreign Application Priority Data
Jul. 15, 2020 (JP) 2020-121215

(51) Int. Cl. G01R 31/12; H01B 13/16; H01B 13/08

(52) U.S. Cl. CPC G01R 31/12; H01B 13/16; H01B 13/08

(57) ABSTRACT

An insulation defect detection method for magnet wire coating includes: a running step of causing a magnet wire to run in a line direction; a first discharge detection step of detecting a first discharge by applying AC voltage to a measurement point on the running magnet wire; a second discharge detection step of detecting a second discharge by applying AC voltage to a measurement point on the magnet wire after the first discharge is detected; and a determination step of determining whether or not the magnet wire coating has an insulation defect by comparing the first discharge with the second discharge.

### TECHNICAL FIELD

The present disclosure relates to an insulation defect detection method and a detection system for magnet wire coating, a manufacturing method for an electric machine, and the electric machine.

### BACKGROUND ART

For a stator of a motor, a coil formed by winding a magnet wire is used. If a pinhole or a flaw occurs in the magnet wire coating, abnormal current flows during operation and the winding wire is abnormally heated, so that there is a possibility of burning.

To solve this problem, disclosed is a method of disposing an electrode for applying voltage for pinhole detection to a running magnet wire and another electrode for applying voltage of several kV on an upstream side of the electrode, and applying detection voltage of several hundred V to a pinhole made visible after high voltage of several kV is applied, to enhance reliability of detection (e.g., Patent Document 1).

### CITATION LIST

### Patent Document

Patent Document 1: Japanese Patent No. 5949612

### SUMMARY OF THE INVENTION

### Problems to be Solved by the Invention

The method disclosed in Patent Document 1 can enhance detection frequency of the pinhole by applying high voltage to the magnet wire, but, when the applied voltage is too high, spark discharge may occur and possibly damage normal coating.

The present disclosure has been made to solve the above problem, and an object of the present disclosure is to provide a detection method and a detection system that can detect an insulation defect without applying excessively high voltage to the entire magnet wire before winding, thus having high reliability.

### Solution to the Problems

An insulation defect detection method for magnet wire coating according to the present disclosure is a method for detecting a defect in magnet wire coating. The detection method includes a running step of causing a magnet wire to run in a line direction; a first discharge detection step of detecting a first discharge by applying AC voltage to a first measurement point on the running magnet wire; a second discharge detection step of detecting a second discharge by applying AC voltage to a second measurement point on the magnet wire after the first discharge is detected; and a determination step of determining whether or not the magnet wire coating has a defect by comparing the first discharge with the second discharge.

An insulation defect detection system for magnet wire coating according to the present disclosure is a system for detecting a defect in magnet wire costing. The detection system includes: a delivery device and a winding device that are respectively disposed in front and back of a running path of a magnet wire and cause the magnet wire to run at a constant speed in a line direction; an AC power supply that generates AC voltage to be applied for detecting discharge from a defect in the magnet wire coating in the running path; a first discharge sensing electrode and a second discharge sensing electrode that are respectively disposed at the first measurement point and the second measurement point to sense the discharge from a defect in the magnet wire coating; a first discharge detection device that detects a discharge signal sensed by the first discharge sensing electrode, and a second discharge detection device that detects a discharge signal sensed by the second discharge sensing electrode; and an evaluation device including a comparison unit that determines whether or not the magnet wire coating has a defect, by comparing the discharge signal of the first discharge detected at the first measurement point with the discharge signal of the second discharge detected at the second measurement point.

A manufacturing method for an electric machine according to the present disclosure includes a step of manufacturing an electric machine using a core wound with the magnet wire inspected by the above insulation defect detection system for magnet wire coating.

An electric machine according to the present disclosure is manufactured using the core wound with the magnet wire inspected by the above insulation defect detection system for magnet wire coating.

### EFFECT OF THE INVENTION

In the insulation defect detection method for magnet wire coating according to the present disclosure, an insulation defect can be detected without applying excessively high voltage to the entire magnet wire before winding, thereby providing a highly reliable detection method.

In the insulation defect detection system for magnet wire coating according to the present disclosure, an insulation defect can be detected without applying excessively high voltage to the entire magnet wire before winding, thereby providing a highly reliable detection system.

In the manufacturing method for an electric machine according to the present disclosure, an insulation defect can be detected without applying excessively high voltage to the entire magnet wire before winding, thereby providing a manufacturing method for an electric machine using the magnet wire inspected by the highly reliable detection system.

In the electric machine according to the present disclosure, an insulation defect can be detected without applying excessively high voltage to the entire magnet wire before winding, thereby providing an electric machine using the magnet wire inspected by the highly reliable detection system.

### BRIEF DESCRIPTION OF THE DRAWINGS

FIG. 1 is a configuration diagram of an insulation defect detection system for magnet wire coating according to Embodiment 1.

FIG. 2 schematically illustrates a delivery device and a winding device of the insulation defect detection system for magnet wire coating according to Embodiment 1.

FIG. 3 illustrates a configuration of a magnet wire of the insulation defect detection system for magnet wire coating according to Embodiment 1.

FIG. 4 illustrates a shape of a discharge sensing electrode of the insulation defect detection system for magnet wire coating according to Embodiment 1.

FIG. 5 illustrates a connection state between the discharge sensing electrode and a discharge detection device, of the insulation defect detection system for magnet wire coating according to Embodiment 1.

FIG. 6 is an equivalent circuit diagram of the connection state between the discharge sensing electrode and the discharge detection device, of the insulation defect detection system for magnet wire coating according to Embodiment 1.

FIG. 7 is a basic flowchart of an insulation defect detection method for magnet wire coating according to Embodiment 1.

FIG. 8 is a flowchart of the insulation defect detection method for magnet wire coating according to Embodiment 1.

FIG. 9 is a configuration diagram of an insulation defect detection system for magnet wire coating according to Embodiment 2.

FIG. 10 is a configuration diagram of an insulation defect detection system for magnet wire coating according to Embodiment 3.

FIG. 11 illustrates a noise removal mechanism of an insulation defect detection system for magnet wire coating according to Embodiment 4.

FIG. 12 illustrates a running stabilization mechanism of an insulation defect defection system for magnet wire coating according to Embodiment 5.

FIG. 13 is a configuration diagram of an insulation defect detection system for magnet wire coating according to Embodiment 6.

FIG. 14 illustrates a smoothing implementation of a discharge waveform of the insulation defect detection system for magnet wire coating according to Embodiment 6.

FIG. 15 illustrates another smoothing implementation of the discharge waveform of the insulation defect detection system for magnet wire coating according to Embodiment 6.

FIG. 16 illustrates still another smoothing implementation of the discharge waveform of the insulation defect detection system for magnet wire coating according to Embodiment 6.

FIG. 17 is a configuration diagram of an insulation defect detection system for magnet wire coating according to Embodiment 7.

FIG. 18 illustrates an application example to a stator core of the insulation defect detection system for magnet wire coating according to Embodiment 7.

FIG. 19 is a block diagram of a hardware configuration example of an evaluation device, of the insulation defect detection system for magnet wire coating.

### DESCRIPTION OF EMBODIMENTS

### Embodiment 1

Embodiment 1 relates to an insulation defect defection system for magnet wire coating including a delivery device and a winding device that are respectively disposed in front and back of a running path of a magnet wire and cause a magnet wire to run at a constant speed in a line direction; an AC power supply that generates AC voltage to be applied for detecting discharge from a defect in magnet wire coating at a first measurement point and a second measurement point in the running path; a first discharge sensing electrode and a second discharge sensing electrode that sense the discharge from a defect in the magnet wire coating; a first discharge detection device and a second discharge detection device that respectively detect a discharge signal sensed by the first discharge sensing electrode and a discharge signal sensed by the second discharge sensing electrode; and an evaluation device that determines whether or not the magnet wire coating has a defect, by comparing the discharge signal detected at the first measurement point with the discharge signal detected at the second measurement point. Furthermore, Embodiment 1 relates to an insulation defect detection method for magnet wire coating using the insulation defect detection system for magnet wire coating.

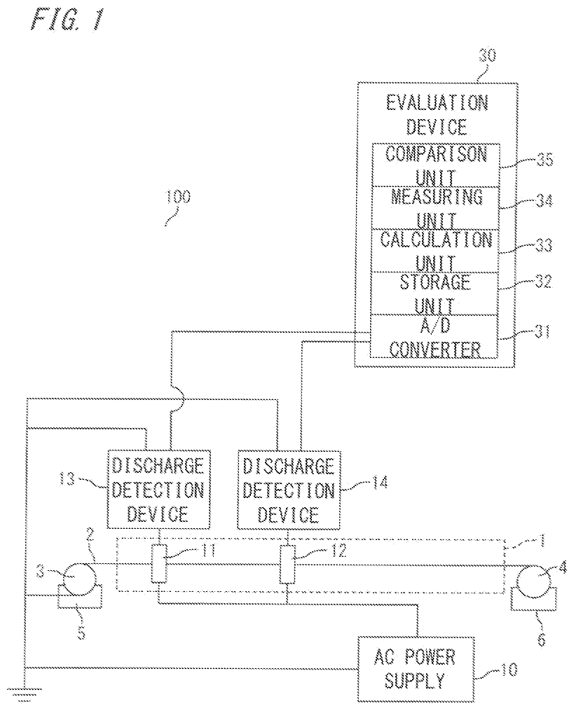

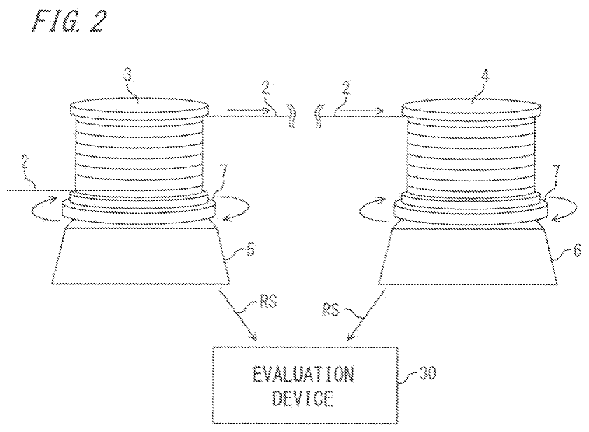

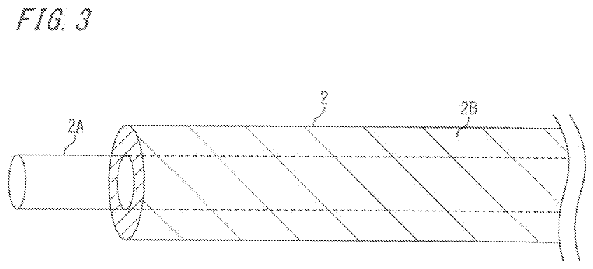

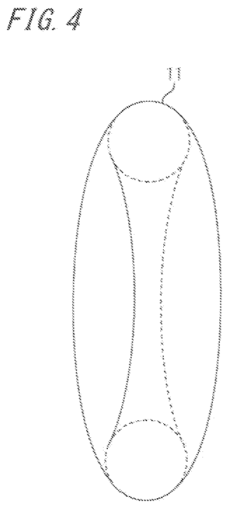

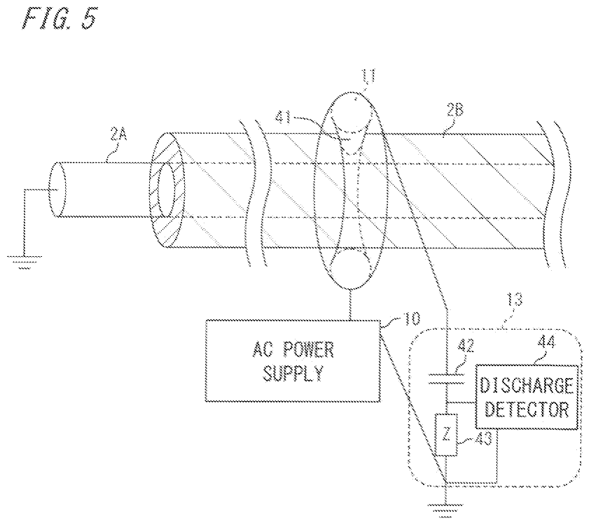

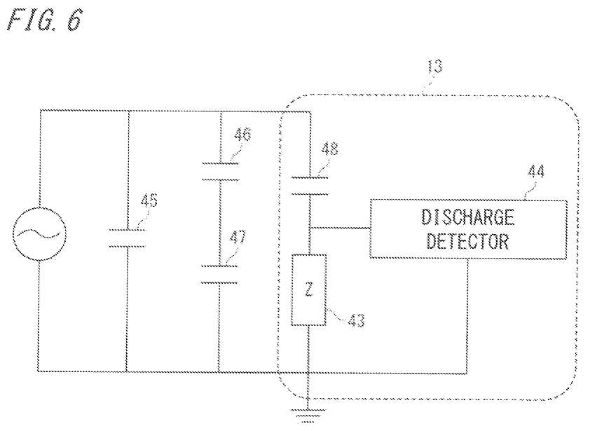

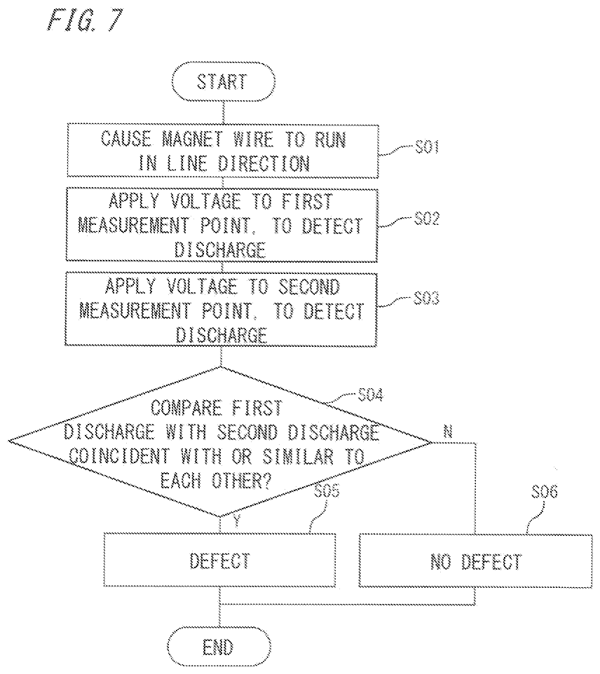

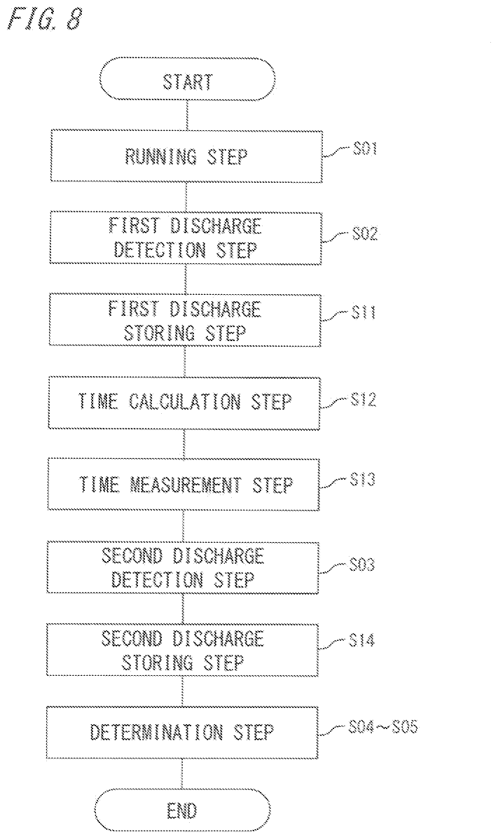

Hereinafter, a configuration, an operation, and a detection method of the insulation defect detection system for magnet wire coating according to Embodiment 1 will be described, with reference to FIG. 1 that is a configuration diagram of the insulation defect detection system for magnet wire coating, FIG. 2 that schematically illustrates the delivery device and the winding device, FIG. 3 that illustrates a configuration of the magnet wire, FIG. 4 that illustrates a shape of the discharge sensing electrode, FIG. 5 that illustrates a connection state between the discharge sensing electrode and the discharge detection device, FIG. 6 that is an equivalent circuit diagram of the connection state between the discharge sensing electrode and the discharge detection device, FIG. 7 that is a basic flowchart of the insulation defect detection method for magnet wire coating, and FIG. 8 that is another flowchart.

In the drawings, the same or corresponding parts are denoted by the same reference characters, and will not be repeatedly described.

First, the configuration of an insulation defect detection system 100 for magnet wire coating according to Embodiment 1 will be described with reference to FIG. 1.

The insulation defect detection system 100 for magnet wire coating according to Embodiment 1 is composed of a running block, a discharge detection block, and an evaluation block.

In FIG. 1, the running block includes a running path 1 of a magnet wire 2, a feeding bobbin 3 for feeding the magnet wire 2 and a winding bobbin 4 for winding the magnet wire 2, and a delivery machine 5 and a winding machine 6.

The discharge detection block includes an AC power supply 10 that generates AC voltage for detecting an insulation defect in magnet wire coating, a first discharge sensing electrode 11 and a second discharge sensing electrode 12, and a first discharge detection device 13 and a second discharge detection device 14.

The evaluation block receives signals from the first and second discharge detection devices 13 and 14 to determine whether or not coating of the magnet wire 2 has an insulation defect, and includes an evaluation device 30. The evaluation device 30 therein includes an A/D converter 31, a storage unit 32, a calculation unit 33, a measuring unit 34, and a comparison unit 35.

First, the running block will be described with reference to FIG. 1, FIG. 2, and FIG. 3.

The feeding bobbin 3 end the winding bobbin 4 are respectively disposed in front and back of the running path 1 of the magnet wire 2. The delivery machine 5 and the winding machine 6 are further provided to the feeding bobbin 3 and the winding bobbin 4, respectively.

Each speed of the delivery machine 5 and winding machine 6 is regulated to cause the magnet wire 2 to run at a constant speed.

The delivery machine 5 and the winding machine 6 may be structured by using a turntable 7 as shown in FIG. 2.

In FIG. 2, “RS” represents a running signal, and this running signal is transmitted from the delivery machine 5 and the winding machine 6 to the evaluation device 30. A role of the running signal will be described below.

Hereinafter, the magnet wire 2 will be described.

The magnet wire 2 is composed of a magnet wire conductor 2A and magnet wire coating 2B as shown in FIG. 3.

As shown in FIG. 1, the magnet wire coating 2B is stripped at a terminal end of the magnet wire 2, where the magnet wire conductor 2A is grounded.

Next, the discharge detection block will be described with reference to FIG. 1 and FIG. 4.

The first discharge sensing electrode 11 and the second discharge sensing electrode 12 are disposed in the running path of the magnet wire 2.

When the first discharge sensing electrode 11 and the second discharge sensing electrode 12 need not be particularly distinguished from each other, they are each referred to as a discharge sensing electrode.

The discharge sensing electrode may be formed in a circular ring shape in cross-section as shown in FIG. 4.

The discharge sensing electrode may be formed of a metal material, such as iron, aluminum, or copper. Alternatively, the discharge sensing electrode may be formed of conductive rubber, a resin material having its surface vapor-deposited with a metal material such as aluminum, or the like.

An internal circumference of a ring of the discharge sensing electrode may be formed so as to fit and be in contact with an external circumference of the magnet wire 2. In addition, the discharge sensing electrode can also be formed so as to leave a margin of about 10 to 100 μm with respect to the magnet wire 2, to avoid abrasion due to contact therebetween.

The first discharge sensing electrode 11 and second discharge sensing electrode 12 formed in such a manner are connected to the AC power supply 10, and AC voltage is applied to them. The AC power supply 10 is grounded at another terminal thereof, in the same manner as the conductor 2A of the magnet wire 2.

The discharge signal sensed at the first discharge sensing electrode 11 is detected by the first discharge detection device 13.

The discharge signal sensed at the second discharge sensing electrode 12 is detected by the second discharge detection device 14.

A specific method for detecting discharge signals by the first and second discharge detection devices 13 and 14 will be described below.

Next, the evaluation block will be described including a relationship with the discharge detection block, with reference to FIG. 1, FIG. 5, and FIG. 6.

The discharge signals detected by the first discharge detection device 13 and the second discharge detection device 14 are A/D converted with a constant sampling frequency by the A/D converter 31 included in the evaluation device 30, and then the A/D converted discharge signals are stored in the storage unit 32.

FIG. 5 illustrates the connection state, using the first discharge sensing electrode 11 and the first discharge detection device 13 as an example. FIG. 6 is the equivalent circuit showing the connection state between the first discharge sensing electrode 11 and the first discharge detection device 13.

FIG. 5 shows a state in which an insulation defect 41 such as a pinhole or a flaw has been caused in the coating 2B of the magnet wire 2.

The first discharge detection device 13 is composed of a coupling Capacitor 42, a detection impedance 43, and a discharge detector 44 connected in parallel with the detection impedance 43.

The AC power supply 10 applies AC voltage to the coupling capacitor 42 and the detection impedance 43 that are connected in parallel with the magnet wire conductor 2A and the coating 2B, through the first discharge sensing electrode 11.

When discharge has been caused to occur from the magnet wire conductor 2A to the first discharge sensing electrode 11, a steep fluctuation occurs in the AC voltage being applied. The discharge detector 44 detects this fluctuation in the AC voltage as a voltage value generated between both ends of the detection impedance 43, when discharge current flows through the detection impedance 43.

FIG. 6 is the equivalent circuit corresponding to the connection state in FIG. 5.

A capacitance 45 in a normal portion of the magnet wire coating, a series circuit including a capacitance 46 in an insulation defect portion of the magnet wire coating and a capacitance 47 in a portion connected in series with the insulation defect portion of the magnet wire coating, and a series circuit including a capacitance 48 of the coupling capacitor and the detection impedance 43 are connected in parallel with the AC power supply.

When discharge has been caused to occur from the magnet wire conductor 2A to the first discharge sensing electrode 11, electric charge caused by discharge is discharged to a grounded point, through a closed circuit composed of the capacitance 46 in the insulation defect portion, the capacitance 47 in the portion connected in series with the insulation defect portion, the capacitance 48 of the coupling capacitor, and the detection impedance 43.

When a discharge electric charge q does not flow through the detection impedance 43, voltage is not generated between both ends of the detection impedance 43. However, when the discharge electric charge q flows, the generated voltage ΔV is sensed according to a formula (1).

ΔV=detection impedance 43×q (1)

Regarding the discharge detector 44, since a commercially available partial discharge measurement device can be used, the details thereof are not described.

When the first discharge sensing electrode 11 senses discharge, the discharge signal from first discharge sensing electrode 11 is stored in the storage unit 32 of the evaluation device 30 via the first discharge detection device 13 and the A/D converter 31.

In addition, when the first discharge sensing electrode 11 senses discharge, the calculation unit 33 included in the evaluation device 30 calculates time t=L/v from a predetermined running speed V and a distance L between the first discharge sensing electrode 11 and the second discharge sensing electrode 12. Here, the time t is time taken until a position (referred to as r) on the magnet wire 2 where the first discharge sensing electrode 11 has sensed discharge reaches the second discharge sensing electrode 12.

The calculation unit 33 outputs this calculation result to the measuring unit 34 included in the evaluation device 30. The measuring unit 34 receives the calculation result from the calculation unit 33 and at the same time starts timer measurement referring to the time t calculated by the calculation unit 33.

In the case where the second discharge sensing electrode 12 has not sensed discharge when the measuring unit 34 finishes timer counting, the sensed discharge is regarded as noise and the discharge signal from the first discharge sensing electrode 11 stored in the storage unit 32 is deleted.

In the case where the second discharge sensing electrode 12 senses discharge after the time t has passed, the discharge signal from the second discharge sensing electrode 12 is also stored in the storage unit 32 via the second discharge detection device 14 and the A/D converter 31.

Next, the calculation unit 33 calculates a feature amount, on the basis of the latest discharge signals of the first discharge sensing electrode 11 and the second discharge sensing electrode 12 stored in the storage unit 32.

On the basis of a calculation result of the calculation unit 33, in the case where the two discharge signals satisfy a predetermined criterion for coincidence or similarity, the comparison unit 35 included in the evaluation device 30 determines that the coating 2B of the magnet wire 2 has an insulation defect.

In the case where the two discharge signals regarding the discharges do not satisfy the criterion for similarity, the sensed discharges are regarded as noise and the discharge signals from the first discharge sensing electrode 11 and the discharge signal from the second discharge sensing electrode 12 stored in the storage unit 32 are deleted.

Determination of whether or not two discharge signals satisfy the criterion for coincidence or similarity is performed on the basis of whether or not a difference between the two discharge signals is within a predetermined range.

Here, determination according to the feature amount of the discharge signal will be described.

As an example of the feature amount of discharge, a peak discharge electric-charge amount of sensed discharge, a duration time of the discharge, a total discharge electric-charge amount of the sensed discharge, or the like, can be used.

The criterion for determination of coincidence or similarity can be that a difference between the two discharges sensed by the first discharge sensing electrode 11 and the second discharge sensing electrode 12 is in a range of a predetermined ratio. In other words, the determination may be performed according to one or a combination of two or more of the peak discharge electric-charge amount, the discharge duration time, and the total discharge electric-charge amount, which are each a feature amount of the discharge signal.

For example, in the case where the criterion is defined as 80%, it can be determined that the coating 2B of the magnet wire 2 has an insulation defect, when all of the peak discharge electric-charge amount, the peak discharge electric-charge amount, and the discharge duration time, of two discharges, match by 80% or more.

As described above, the discharge signal sensed by the first discharge sensing electrode 11, and the discharge signal that is sensed by the second discharge sensing electrode 12 after the time t has passed and can be regarded as coincident with or similar to the discharge signal sensed by the first discharge sensing electrode 11 are sequentially stored. As described above, the discharge signal from the first discharge sensing electrode 11 and the discharge signal from the second discharge sensing electrode 12 are stored in a pair, and thus, during a detection operation of an insulation defect (pinhole or flaw) in the magnet wire 2, the number of occurrences of insulation defects can be grasped from the number of pieces of data stored.

After the measuring unit 34 starts measurement, running of the magnet wire 2 may stop before the measurement is finished. In this regard, the running signal (RS) is transmitted from one or both of the delivery machine 5 and the winding machine 6 to the measuring unit 34 all the time. The measuring unit 34 continues the measurement while receiving the running signal, but stops the measurement when receiving no running signal, whereby the stop of running can be coped with.

Although the running signal (RS) is transmitted from the delivery machine 5 and/or the winding machine 6 all the time in the above description, a running stop signal may be transmitted from the delivery machine 5 and/or the winding machine 6.

As described above, the insulation defect detection system for magnet wire coating according to Embodiment 1 is described focusing on the configuration, function, and operation thereof. Hereinafter, the insulation defect detection method for magnet wire coating will be described with reference to the basic flowchart in FIG. 7 and the flowchart in FIG. 8.

A basic process of the insulation defect detection method for magnet wire coating is composed of a running step (S01), a first discharge detection step (S02), a second discharge detection step (S03), a second discharge detection step (S03), and a determination step (S04 to S06).

In the running step (S01), the magnet wire 2 is caused to run in the line direction.

In the first discharge detection step (S02), AC voltage is applied to the first measurement point on the running magnet wire 2 to detect a first discharge.

In the second discharge detection step (S03), AC voltage is applied to the second measurement point on the magnet wire 2 to detect a second discharge.

In the determination step (S04 to S06), the first discharge and the second discharge are compared. When the two discharge signals are coincident with or similar to each other, the coating 2B of the magnet wire 2 is determined to have an insulation defect. When they are not coincident with or similar to each other, the coating 2B of the magnet wire 2 is determined to have no insulation defect.

Next, an entire process of the insulation defect detection method for magnet wire coating described in Embodiment 1 will be described.

In the entire process, a first discharge storing step S11 to a second discharge storing step S14 are provided in addition to the running step (S01) to the determination step (S04 to S06) described in the basic process. Hereinafter, contents of the newly added process, other than the basic process, will be described.

In the first discharge storing step (S11), when the first discharge sensing electrode 11 senses discharge, the discharge signal is stored in the storage unit 32 via the first discharge detection device 13.

In a time calculation step (S12), when the first discharge sensing electrode 11 senses discharge, the calculation unit 33 calculates the time t taken until the position on the magnet wire 2 where the first discharge sensing electrode 11 has sensed discharge reaches the second discharge sensing electrode 12.

In a time measurement step (S13), the measuring unit 34 receives this calculation result t from the calculation unit 33, and at the same time starts timer measurement.

In the second discharge storing step (S14), the discharge signal sensed by the second discharge sensing electrode 12 is stored in the storage unit 32 via the second discharge detection device 14.

Although not shown in the flowchart in FIG. 8, a discharge feature amount calculation stop and a magnet wire running sensing step are included as processing steps of the insulation defect detection method for magnet wire coating.

In the discharge feature amount calculation step, the peak discharge electric-charge amount, the duration time, and the total discharge electric-charge amount of discharges sensed by the first discharge sensing electrode 11 and the second discharge sensing electrode 12 are calculated.

In the magnet wire running sensing step, the measuring unit 34 continues the measurement while receiving the running signal from the delivery machine 5 and/or the winding machine 6, but stops the measurement when receiving no running signal.

As described above, Embodiment 1 relates to the insulation defect detection system for magnet wire coating including the delivery device end the winding device that are respectively disposed in front and back of the running path of the magnet wire and cause the magnet wire to run at the constant speed in the line direction; the AC power supply than generates AC voltage to be applied for detecting discharge from a defect in the magnet wire coating at the first measurement point and the second measurement point in the running path; the first discharge sensing electrode and the second discharge sensing electrode that sense the discharge from a defect in the magnet wire coating; and the first discharge detection device and the second discharge detection device that respectively detect the discharge signal sensed by the first discharge sensing electrode and the discharge signal sensed by the second discharge sensing electrode, and whether or not the magnet wire coating has a defect is determined by comparing the discharge signal detected at the first measurement point with the discharge signal detected at the second measurement point. Furthermore, Embodiment 1 relates to the insulation defect detection method for magnet wire coating using the insulation defect detection system for magnet wire coating.

Therefore, the insulation defect detection system and detection method for magnet wire coating according to Embodiment 1 can detect an insulation defect without applying excessively high voltage to the entire magnet wire before winding, thereby improving the reliability.

### Embodiment 2

An insulation defect detection system for magnet wire coating according to Embodiment 2 includes a charge eliminating electrode in the running path of the magnet wire to eliminate electric charge staying on the magnet wire coating.

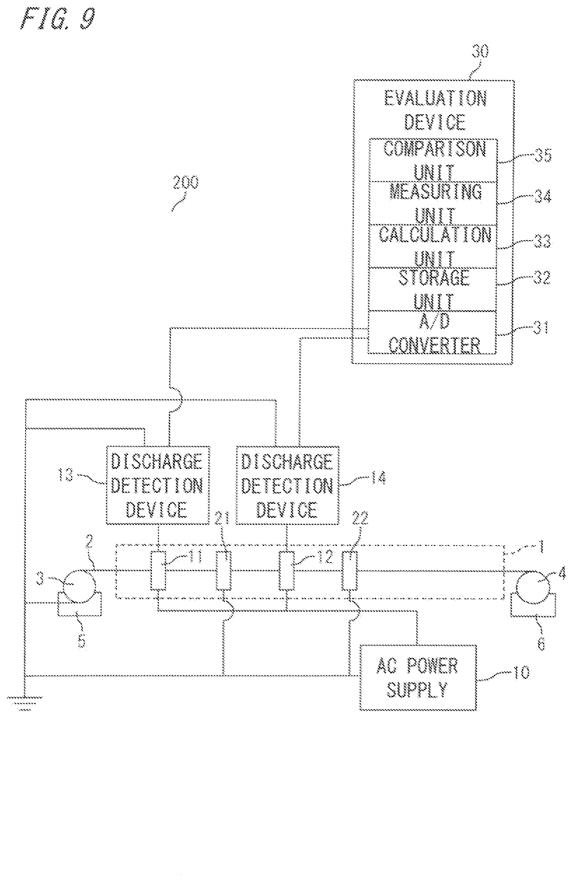

The insulation defect detection system for magnet wire coating according to Embodiment 2 will be described focusing on differences from Embodiment 1, with reference to FIG. 9 that is a configuration diagram of the insulation defect detection system for magnet wire coating.

In the configuration diagram according to Embodiment 2, parte that are the same as or correspond to those in Embodiment 1 are denoted by the same reference characters.

For discrimination from Embodiment 1, the insulation defect detection system for magnet wire coating is denoted by 200.

It is conceivable that electric charge stays on an outer surface of the coating 2B of the magnet wire 2, when AC voltage is applied to the magnet wire 2. In the running path 1 in FIG. 1 according to Embodiment 1, AC voltage applied to a position (referred to as r) on the magnet wire 2 from the first discharge sensing electrode 11 may cause electric charge to stay in the position r. In that case, the staying electric charge influences the sensing accuracy of the second discharge sensing electrode 12 in the position r.

In addition, when the charged magnet wire 2 is wound by the winding bobbin 4, discharge may occur due to non-uniformity of the staying electric charge and thus an insulation defect (pinhole or flaw) may be newly generated.

In the running path 1 in FIG. 9, in addition to the machine and the device included in the discharge detection block described in Embodiment 1, a first charge eliminating electrode 21 is disposed between the first discharge sensing electrode 11 and the second discharge sensing electrode 12. The first charge eliminating electrode 21 eliminates electric charge staying on the outer surface of the coating 2B of the magnet wire 2, with AC voltage applied from the first discharge sensing electrode 21.

Furthermore, a second charge eliminating electrode 22 is disposed downstream of the second discharge sensing electrode 12. The second charge eliminating electrode 22 eliminates staying electric charge, with the AC voltage applied from the second discharge sensing electrode 12.

The two first and second charge eliminating electrodes 21 and 22 are grounded, and electric charge staying on the outer surface of the magnet wire coating 2B is eliminated between the first discharge sensing electrode 11 and the second discharge sensing electrode 12, and at a portion downstream of the second discharge sensing electrode 12.

As described above, the insulation defect detection system for magnet wire coating according to Embodiment 2 includes the charge eliminating electrodes in the running path of the magnet wire to eliminate electric charge staying on the coating of the magnet wire.

Therefore, the insulation defect detection system for magnet wire coating according to Embodiment 2 can detect an insulation defect without applying excessively high voltage to the entire magnet wire before winding, thereby improving the reliability. Furthermore, the sensing accuracy of the discharge sensing electrode is improved, thereby preventing an insulation defect from being newly generated.

### Embodiment 3

In an insulation defect detection system for magnet wire coating according to Embodiment 3, one or more discharge sensing electrodes are further added to the first discharge sensing electrode and the second discharge sensing electrode, to dispose three or more discharge sensing electrodes. In the insulation defect detection method for magnet wire coating according to Embodiment 3, third to Nth (N is an integer of 3 or more) discharge detection steps are further added to the first and second discharge detection steps.

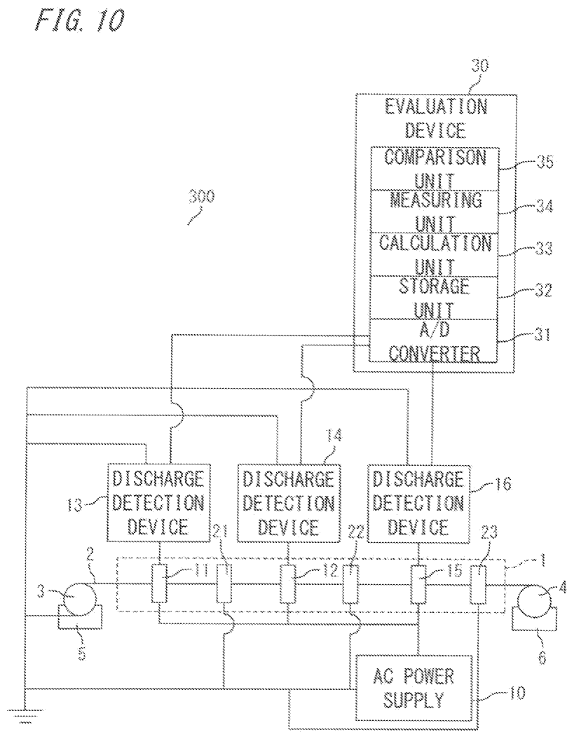

The configuration and the operation of the insulation defect detection system for magnet wire coating according to Embodiment 3 will be described focusing on differences from Embodiment 1, with reference to FIG. 10 that is a configuration diagram of the insulation defect detection system for magnet wire coating.

In the configuration diagram according to Embodiment 3, parts that are the same as or correspond to those in Embodiment 1 or 2 are denoted by the same reference characters.

For discrimination from Embodiment 1, the insulation defect detection system for magnet wire coating is denoted by 300.

If an insulation defect (pinhole or flaw) in the coating 2B of the magnet wire 2 is small, discharge is unstable, and therefore, for example, there is a possibility that the first discharge sensing electrode 11 has sensed discharge but the second discharge sensing electrode 12 does not sense the discharge. On the contrary, there is a possibility that the first discharge sensing electrode 11 has not sensed discharge but the second discharge sensing electrode 12 senses the discharge.

It is also conceivable that both of the first discharge sensing electrode 11 and the second discharge sensing electrode 12 have sensed discharge, but a matching rate of the feature amounts, such as the peak discharge electric-charge amount, the discharge duration time, and the total discharge electric-charge amount of the discharge described in Embodiment 1 is low due to instability of the discharge and thus the discharge cannot be determined to come from an insulation defect.

In Embodiment 1, the above three examples are determined to be noise, so that the insulation defect is overlooked. As a countermeasure for the above, it is effective to dispose three or more discharge sensing electrodes for sensing discharge.

FIG. 10 shows an example in which a third discharge sensing electrode 15 is disposed downstream of the second discharge sensing electrode 12, in addition to the first discharge sensing electrode 11 and the second discharge sensing electrode 12, to dispose three discharge sensing electrodes.

The third discharge sensing electrode 15 is disposed such that an interval between the third discharge sensing electrode 15 and the second discharge sensing electrode 12 is the same as an interval between the first discharge sensing electrode 11 and the second discharge sensing electrode 12. The third discharge sensing electrode 15 is connected to a third discharge detection device 16, and the discharge signal sensed by a third discharge sensing electrode 15 is detected by the third discharge detection device 16.

In addition, a third charge eliminating electrode 23 described in Embodiment 2 is disposed downstream of the third discharge sensing electrode 15. As a combination in detection of an insulation defect in the coating 2B of the magnet wire 2, the following seven combinations are conceivable.

(1) All of the first discharge sensing electrode 11, the second discharge sensing electrode 12, and the third discharge sensing electrode 15 sense discharge, and the feature amounts of all the discharge signals can be regarded as coincident with or similar to each other.

(2) All of the first discharge sensing electrode 11, the second discharge sensing electrode 12, and the third discharge sensing electrode 15 sense discharge, and the discharge signals sensed by the first discharge sensing electrode 11 and the second discharge sensing electrode 12 can be regarded as coincident with or similar to each other.

(3) All of the first discharge sensing electrode 11, the second discharge sensing electrode 12, and the third discharge sensing electrode 15 sense discharge, and the discharge signals sensed by the first discharge sensing electrode 11 and the third discharge sensing electrode 15 can be regarded as coincident with or similar to each other.

(4) All of the first discharge sensing electrode 11, the second discharge sensing electrode 12, and the third discharge sensing electrode 15 sense discharge, and the discharge signals sensed by the second discharge sensing electrode 12 and the third discharge sensing electrode 15 can be regarded as coincident with or similar to each other.

(5) The first discharge sensing electrode 11 and the second discharge sensing electrode 12 sense discharge, and the discharge signals sensed by the first discharge sensing electrode 11 and the second discharge sensing electrode 12 can be regarded as coincident with or similar to each other.

(6) The first discharge sensing electrode 11 and the third discharge sensing electrode 15 sense discharge, and the discharge signals sensed by the first discharge sensing electrode 11 and the third discharge sensing electrode 15 can be regarded as coincident with or similar to each other.

(7) The second discharge sensing electrode 12 and the third discharge sensing electrode 15 sense discharge, and the discharge signals sensed by the second discharge sensing electrode 12 and the third discharge sensing electrode 15 can be regarded as coincident with or similar to each other.

In Embodiment 1, an insulation defect (pinhole or flaw) can be detected in only the above cases (1), (2), and (5), but, as described above, an insulation defect (pinhole or flaw) can be detected in all the cases (1) to (7) by only adding one discharge sensing electrode, thereby improving the detection capability by 2.3 times.

In Embodiment 3, the example in which one discharge sensing electrode is added to dispose the three discharge sensing electrodes is described, but even more discharge sensing electrodes may be added to dispose four or more discharge sensing electrodes. That is, providing N (N is an integer of 3 or more) or more discharge sensing electrodes can further improve an insulation defect detection capability.

In the insulation defect detection method for magnet wire coating, in addition to the first discharge detection step and the second discharge detection step, the third to Nth (N is an integer of 3 or more) discharge detection steps of detecting discharge with AC voltage applied to each measurement point on the magnet wire 2 are sequentially provided. Then, in the determination step, the discharge signals detected in the third to Nth discharge detection steps are additionally compared, and it is determined whether or net the magnet wire coating 2B has the insulation defect.

As described above, in the insulation defect detection system for magnet wire coating according Embodiment 3, one or more discharge sensing electrodes are added to the first discharge sensing electrode and the second discharge sensing electrode, to dispose three or more discharge sensing electrodes. In the insulation defect detection method for magnet wire coating according to Embodiment 3, the third to Nth (N is an integer at 3 or more) discharge detection steps are added to the first and second discharge detection steps.

Therefore, the insulation defect detection system and detection method for magnet wire coating in Embodiment 3 can detect an insulation defect without applying excessively high voltage to the entire magnet wire before winding, thereby improving the reliability. Furthermore, the insulation defect detection capability for the magnet wire coating can be further improved.

### Embodiment 4

An insulation defect detection system for magnet wire coating according to Embodiment 4 includes a reference signal generator to remove noise. In the insulation defect detection method for magnet wire coating according to Embodiment 4, a reference signal generation step to remove noise is added.

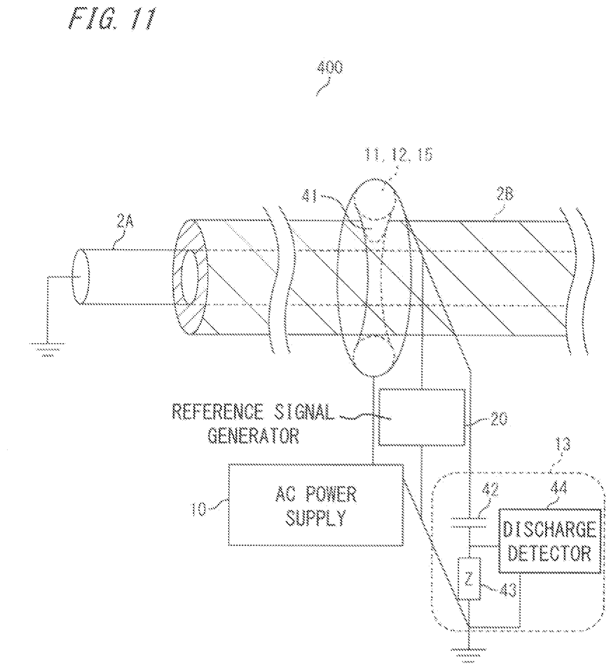

The insulation defect detection system for magnet wire coating according to Embodiment 4 will be described focusing on differences from Embodiment 1, with reference to FIG. 11 that illustrates a noise signal removal mechanism of the insulation defect detection system for magnet wire coating.

In a configuration diagram according to Embodiment 4, parts that are the same as or correspond to those in Embodiment 1 are denoted by the same reference characters.

In a description of the insulation defect detection system for magnet wire coating according to Embodiment 4. FIG. 10 that is the configuration diagram of the insulation defect detection system for magnet wire coating according to Embodiment 3 is referred to as necessary.

For discrimination from Embodiment 1, the insulation defect detection system for magnet wire coating is denoted by 400.

As a factor that obstructs detection of an insulation defect (pinhole or flaw) in the magnet wire costing 2B, the following two factors are assumed.

(1) Potential of each grounded point for grounding the conductor 2A of the magnet wire 2, the AC power supply 10, the first charge eliminating electrode 21, the second charge eliminating electrode 22, and the third charge eliminating electrode 23 is unstable. This causes the first discharge sensing electrode 11, the second discharge sensing electrode 12, and the third discharge sensing electrode 15 to sense noise unrelated to discharge. Then the sensed noise is a disturbance factor in calculation of the feature amount of the discharge signal and, furthermore, in determination of whether or not the discharge signals are coincident with or similar to each other.

(2) Discharge also occurs from a surface of the normal coating 2B of the magnet wire 2 at a lower level than that from an insulation defect. Thus, the discharge is a disturbance factor in calculation of the feature amount of the discharge signals sensed by the first discharge sensing electrode 11, the second discharge sensing electrode 12, and the third discharge sensing electrode 15, and, furthermore, in determination of whether or not the discharge signals are coincident with or similar to each other.

As a countermeasure for the disturbance noise and discharge from a surface of the magnet wire coating 2B, unwanted noise unrelated to discharge from an insulation defect needs to be removed as much as possible.

A method example for this will be described with reference to FIG. 11.

In a state in which voltage from the AC power supply 10 is not applied, a reference signal of a constant electric-charge amount, for example, 100 picocoulombs is generated. The reference signal generator 20 is connected so as to be in parallel with magnet wire coating 2B, and generates the reference signal.

This reference signal is sensed by the first, second, and third discharge sensing electrodes 11, 12, 15, transmitted to the storage unit 32 via each of the first, second, and third discharge detection devices 13, 14, 16 and the A/D converter 31, and stored in the storage unit 32.

In the subsequent process, the signal with intensity of the reference signal or lover is not stored. For example, the signal with intensity of the reference signal or lower is removed from the discharge signals.

In the case where the signal with intensity of the reference signal or lower is removed in this manner, even if weak noise unrelated to discharge from an insulation defect in magnet wire coating 2B is sensed in the first, second, and third discharge sensing electrodes 11, 12, 15, the sensed noise can be removed. Consequently, the insulation defect detection capability for the magnet wire coating can be further improved.

The insulation defect detection method for magnet wire coating includes a reference signal transmission step of transmitting the reference signal. The reference signal is detected in the first, second, and third discharge sensing electrodes 11, 12, 15 in advance, and the discharge signal with intensity of the reference signal or lower is removed in the discharge storing step.

As described above, the insulation defect detection system for magnet wire coating according to Embodiment 4 includes the reference signal generator to remove noise. In the insulation defect detection method for magnet wire coating according to Embodiment 4, the reference signal generation step is added to remove noise.

Therefore, the insulation defect detection system and detection method for magnet wire coating according to Embodiment 4 can detect an insulation defect without applying excessively high voltage to the entire magnet wire before winding, thereby improving the reliability. Furthermore, the insulation defect detection capability for the magnet wire coating can be further improved.

### Embodiment 5

An insulation defect detection system for magnet wire coating according to Embodiment 5 includes a stabilization mechanism in the running path of the magnet wire.

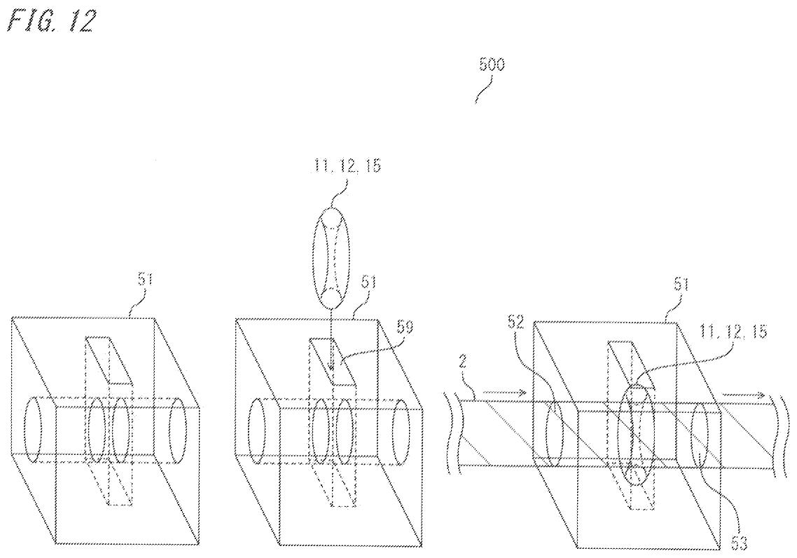

The insulation defect detection system for magnet wire coating according to Embodiment 5 will be described focusing on differences from Embodiment 1, with reference to FIG. 12 that illustrates the stabilization mechanism in the running path of the magnet wire.

In a configuration diagram according to Embodiment 5, parts that are the same as or correspond to those in Embodiment 1 are denoted by the same reference characters.

For discrimination from Embodiment 1, the insulation defect detection system for magnet wire coating is denoted by 500.

To simplify the description, when the first, second, and third discharge sensing electrodes 11, 12, 15 need not be discriminated from each other, they are simply referred to as each discharge sensing electrode as appropriate.

The factor that obstructs detection of an insulation defect (pinhole or flaw) in the magnet wire coating 2B includes instability in the running path 1 of the magnet wire 2. Slight meandering of the running path 1 or slight vibration changes the contact state or the distance between the magnet wire 2, and each of the first, second, and third discharge sensing electrodes 11, 12, 15.

While the magnet wire 2 is in good contact with each discharge sensing electrode, discharge with high intensity can be stably sensed. However, when the contact is insufficient or unstable, the intensity of the discharge is low and unstable, so that the first, second, and third discharge sensing electrodes 11, 12, 15 cannot stably sense discharge.

While the distance between the magnet wire 2 and each discharge sensing electrode is properly maintained, discharge with high intensity can be stably sensed. However, when the distance is long or unstable, the discharge has low intensity and is unstable, so that the first, second, and third discharge sensing electrodes 11, 12, 15 cannot stably sense discharge.

To solve these problems, it is effective to dispose the stabilization mechanism in the running path 1 of the magnet wire 2.

Guide blocks 51 as shown in FIG. 12 may be disposed to guide the magnet wire 2 to each discharge sensing electrode.

In other words, the guide block 51 having a substantially cube shape is provided with a through hole including a guide hole 52 on an upstream side and a guide hole 53 on a downstream side, and with a groove 59 for storing each of the first, second, and third discharge sensing electrodes 11, 12, 15 in the guide block 51. Each of the first, second, and third discharge sensing electrodes 11, 12, 15 is stored in this groove 59. The provided through hole penetrates two faces opposite to each other across a circular face of each discharge sensing electrode, and has a center point coincident with that of each discharge sensing electrode, and an inner diameter larger than the outer diameter of the magnet wire 2 by about 10 to 100 μm.

The magnet wire 2 is caused to pass through the guide hole 52 on the upstream side of the guide block 51, to approach and pass through the first, second, and third discharge sensing electrodes 11, 12, 15 while keeping a stable contact state or a proper distance from each other, and go out of the guide hole 53 on the downstream side. In this manner, when the stabilization mechanism is disposed in the running path of the magnet wire 2, the first, second, and third discharge sensing electrodes 11, 12, 15 can constantly sense discharge with high intensity.

In FIG. 12, an example of the guide block 51 that stores one discharge sensing electrode is shown, but the guide block may be lengthened in a running direction of the magnet wire 2 to store a plurality of the discharge sensing electrodes therein. In addition, the guide block 51 may be retained on a cradle (not shown) in the running path.

Considering damage of the magnet wire 2 due to abrasion, the guide block 51 is preferably formed of a resin material, and, mere preferably, fluorinated resin such as polytetrafluoroethylene (PTFE) with a low coefficient of friction.

Alternatively, when the guide block 51 is formed of a metal material, such as iron, aluminum, or copper, the discharge sensing electrode is not stored in the guide block 51. Instead, an inner diameter of a hole forming the running path 1 of the magnet wire 2 and penetrating through the guide block is adjusted to be larger than the outer diameter of the magnet wire 2 by about 10 to 100 μm, and this structure can be used as a discharge sensing electrode.

In the present Embodiment 5, an example of the guide structure for guiding the magnet wire 2 is shown in FIG. 12. However, the guide structure is not limited to this example. Any structure may be applicable, as long as the same function is included.

As described above, the insulation defect detection system for magnet wire coating according to Embodiment 5 includes the stabilization mechanism in the running path of the magnet wire.

Therefore, the insulation defect detection system for magnet wire coating according to Embodiment 5 can detect an insulation defect without applying excessively high voltage to the entire magnet wire before winding, thereby improving the reliability. Furthermore, the insulation defect detection capability for the magnet wire coating can be further improved.

### Embodiment 6

An insulation defect detection system for magnet wire coating according to Embodiment 6 performs smoothing processing on the discharge signal to reduce noise. In the insulation defect detection method for magnet wire coating according to Embodiment 6, the smoothing processing is added in the determination step, to reduce noise.

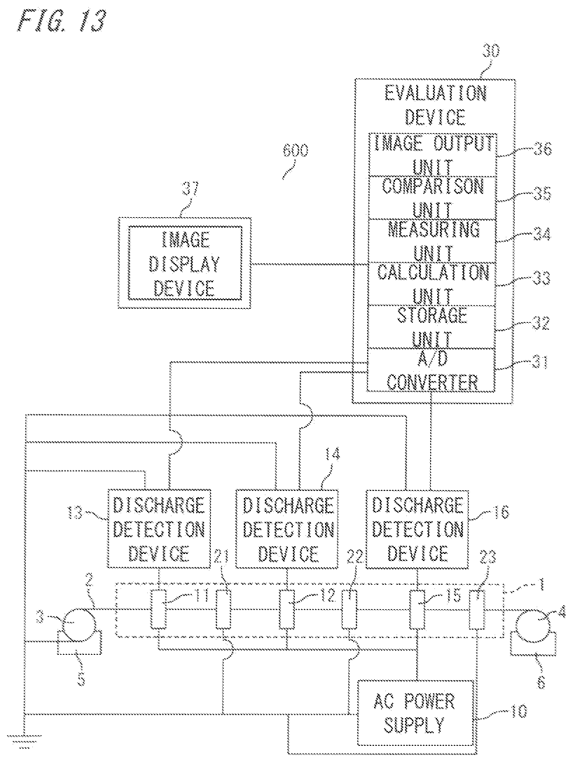

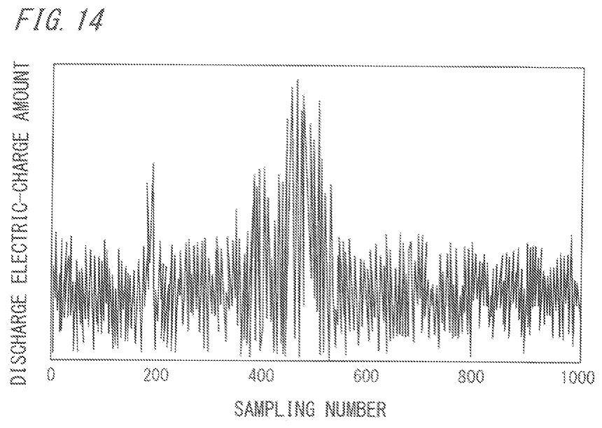

The insulation defect detection system for magnet wire coating according to Embodiment 6 will be described focusing on differences from Embodiment 1, with reference to FIG. 13 that is a configuration diagram of the insulation defect detection system for magnet wire coating and FIG. 14 to FIG. 16 that each illustrate a smoothing implementation of a discharge waveform.

In the configuration diagram according to Embodiment 6, parts that are the same as or correspond to those in Embodiment 1 are denoted by the same reference characters.

For discrimination from Embodiment 1, the insulation defect detection system for magnet wire coating is denoted by 600.

In the insulation defect detection system 600 for magnet wire coating, an image output unit 36 included in the evaluation device 30 and an image display device 37 are added to the evaluation block.

Another effective method for reducing unwanted noise, that is, a factor that obstructs detection of an insulation defect (pinhole or flaw) in the magnet wire coating 2B is to perform the smoothing processing on the discharge signal stored in the storage unit 32.

FIG. 14 simulatively shows the discharge signal detected by the insulation defect detection system for magnet wire coating according to the present disclosure and stored in the storage unit 32.

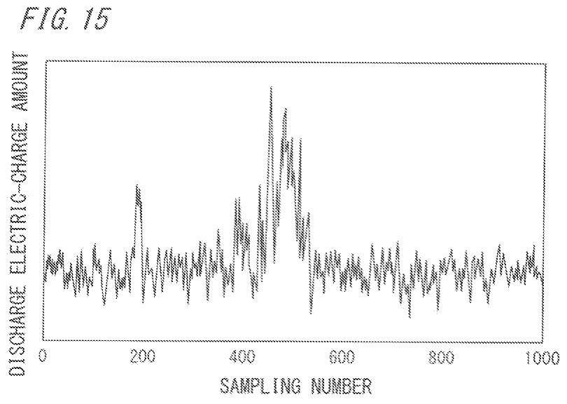

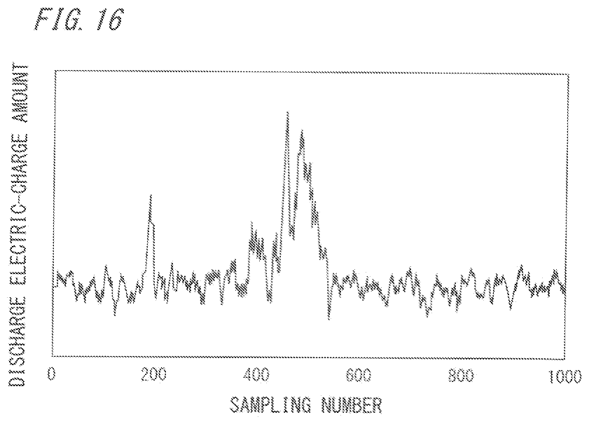

In FIG. 14, a horizontal axis indicates a sampling number, and a vertical axis indicates a discharge electric-charge amount. The same applies to FIG. 15 and FIG. 16.

To simplify calculation, a sampling frequency to the storage unit 32 is assumed to be 256 Hz.

In a vicinity of 500 points in a horizontal axis direction of a graph in FIG. 14, a strong discharge peak assumed to be discharge from an insulation defect in magnet wire coating 2B is recognized. Since noises in a vicinity of 400 points and 550 points are large, a whole picture of a peak shape is difficult to be grasped. Accordingly, accurate calculation of the feature amounts, such as the discharge duration time and the total discharge electric-charge amount, related to this peak is difficult to be performed.

In this case, the smoothing processing of the discharge signal shown in FIG. 15 is considered.

In Embodiment 6, simple moving average processing is performed as an example of the smoothing processing.

On the basis of the latest discharge signals of the first discharge sensing electrode 11 and the second discharge sensing electrode 12 stored in the storage unit 32, the calculation unit 33 performs the moving average processing according to a predetermined number of moving average points, and then performs calculation of the feature amount.

In FIG. 15, a result when the number of moving average points is 5 is shown. In FIG. 16, another result when the number of moving average points is 9 is shown. In each of the discharge signal waveform in FIG. 15 and the discharge signal waveform in FIG. 16, an influence on a main discharge signal due to unwanted noise is removed, so that the whole picture of the peak shape is clear. Thus, when the discharge signal waveform in FIG. 15 or FIG. 16 is used, the discharge duration time and the total discharge electric-charge amount can be assuredly grasped.

The comparison unit 35 determines whether or not there is discharge from an insulation defect in magnet wire coating 2B, on the basis of a calculation result of the calculation unit 33. If the number of moving average points is excessively increased, an absolute value of the discharge peak is reduced. However, in Embodiment 6, determination of whether the signals are coincident with or similar to each other is performed by relatively comparing the discharge signal sensed by the first discharge sensing electrode 11 with the discharge signal sensed by the second discharge sensing electrode 12 as described in Embodiment 1. Thus, reduction in the absolute value does not influence detection of an insulation defect in magnet wire coating 2B.

It is effective that the insulation defect detection system for magnet wire coating is tested in advance to obtain a proper number of moving average points. In other words, in a range in which the detection capability is not lowered, the number of moving average points is set according to a workplace environment where a detection operation of an insulation defect in magnet wire coating 2B is performed and the discharge amount from the coating 2B of the normal magnet wire 2.

As shown in the configuration diagram in FIG. 13, after the determination is performed, both of the discharge signal waveform and a cumulative number or discharge signals from an insulation defect in magnet wire coating 2B can be outputted to the image display device 37 through the image output unit 36 of the evaluation device 30, and displayed by the image display device 37.

Such a configuration enables an operator to confirm a detection state of an insulation defect in magnet wire coating 2B at all times.

In this manner, the insulation defect detection system for magnet wire coating according to Embodiment 6 performs the smoothing processing to reduce unwanted noise, thereby further improving the insulation defect detection capability for the magnet wire coating.

In the insulation defect detection method for magnet wire coating according to Embodiment 6, the smoothing processing is performed on the waveform of the detected discharge signal in the determination step.

As described above, the insulation defect detection system for magnet wire coating according to Embodiment 6 performs the smoothing processing on the discharge signal to reduce noise. In the insulation defect detection method for magnet wire costing according to Embodiment 6, the smoothing processing is added to the determination step to reduce noise.

Therefore, the insulation defect detection system and detection method for magnet wire coating according to Embodiment 6 can detect an insulation defect without applying excessively high voltage to the entire magnet wire before winding, thereby improving the reliability. Furthermore, the insulation defect detection capability for the magnet wire coating can be further improved.

### Embodiment 7

An insulation defect detection system and a detection method for magnet wire coating according to Embodiment 7 are applied to a winding process for a stator which is an armature of a rotary electric machine or a linear motion machine as an example of an electric machine.

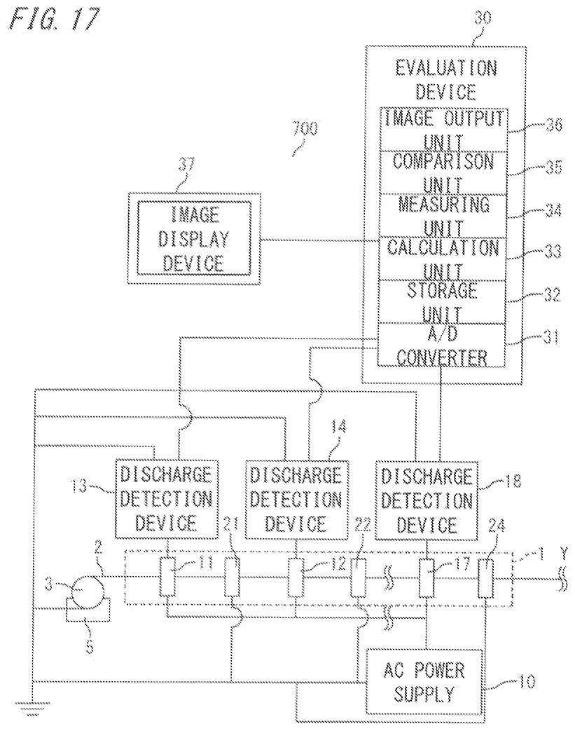

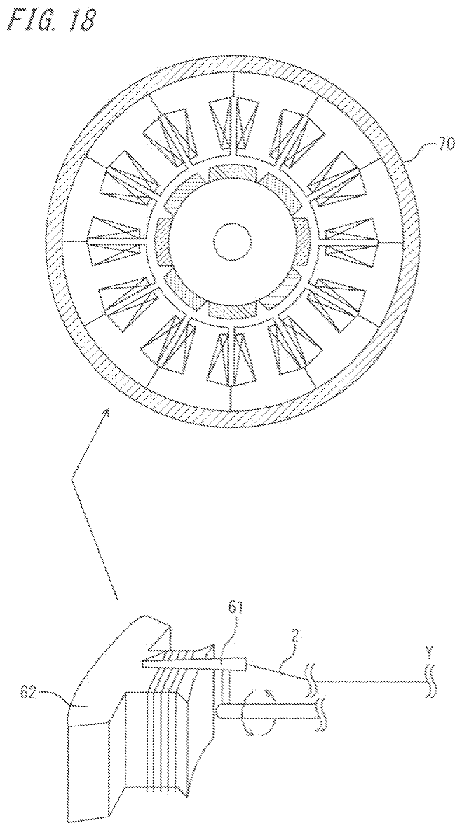

The insulation defect detection system for magnet wire coating according to Embodiment 7 will be described focusing on differences from Embodiment 1, with reference to FIG. 17 that is a configuration diagram of the insulation defect detection system for magnet wire coating and FIG. 18 that illustrates an application example to a stator core.

In the configuration diagram according to Embodiment 7, parts that are the same as or correspond to those in Embodiment 1 are denoted by the same reference characters.

For discrimination from Embodiment 1, the insulation defect detection system for magnet wire coating is denoted by 700.

In the insulation defect detection system 700 for magnet wire coating in FIG. 17, only the feeding bobbin 3 for feeding the magnet wire 2 is disposed in the running block.

The discharge detection block includes the AC power supply 10, the first discharge sensing electrode 11, the second discharge sensing electrode 12, and a fourth discharge sensing electrode 17, and the first discharge detection device 13, the second discharge detection device 14, and a fourth discharge detection device 18. The discharge detection block further includes the first charge eliminating electrode 21, the second charge eliminating electrode 22, and a fourth charge eliminating electrode 24. In FIG. 17, the third discharge sensing electrode 15, the third discharge detection device 16, and the third charge eliminating electrode 23 are not shown.

In the insulation defect detection system and detection method for magnet wire coating described in Embodiment 1 to Embodiment 6, the magnet wire 2 passes through the running path 1 of the magnet wire 2 to undergo an insulation defect inspection of the magnet wire coating, and then, is delivered to a winding machine (not shown) not to the winding bobbin 4, as indicated by a sign “Y” in each of FIG. 17 and FIG. 18.

The winding machine sequentially winds the inspected magnet wire 2 by a nozzle 61 of the winding machine, around the stator core 62.

In this case, it is considered when the insulation defect detection system 700 for magnet wire coating has determined that there is discharge from an insulation defect (pinhole or flaw) in the magnet wire coating 2B, according to the discharge signals from the first, second, third, and fourth discharge sensing electrodes 11, 12, 15, 17.

A running path length XL of the magnet wire 2 between an electrode that has first sensed the discharge determined to be coincident with or similar to another discharge, among the discharge sensing electrodes that have sensed the discharge signals determined to be coincident with or similar to each other, and the stator 62 on which winding is to be performed is determined. The calculation unit 33 calculates time T=XL/V from a running speed V and the running path length XL, and transmits the time T to the measuring unit 34. Here, the time T is time taken until the insulation defect in magnet wire costing 2B reaches the stator core 62 on which winding is being performed.

The measuring unit 34 receives a calculation result from the calculation unit 33 and at the same time starts timer measurement from the time when the discharge has been determined to come from the insulation defect in the magnet wire coating 2B. Consequently, the stator core 62 on which winding is being performed when the measuring unit 34 finishes the measurement is specified.

The stator core 62 on which winding has been performed and specified to include an insulation defect in the magnet wire 2 as described above, or the stator using this stator core 62 is not passed to the subsequent process. Such a stator core 62 or such a stator can be discriminated from a good product by means of being transferred to a conveyor, a trolley, or the like for sending out defective products as a defective product, or the like.

Alternatively, such a defective stator core may be individually re-inspected by a method such as a known surge voltage application (impulse voltage application).

As described in Embodiment 1, before the measuring unit 34 finishes measurement of a predetermined time, running of the magnet wire 2 may be stopped due to a stop of the winding machine. In that case, the measuring unit 34 may receive the winding operating signal from the winding machine and continue the measurement only while receiving the winding operating signal, as in Embodiment 1.

In addition, the measuring unit 34 may receive the winding operation step signal from the winding machine.

FIG. 18 shows an electric machine 70 including the stator core 62 wound with the magnet wire 2 confirmed to have no insulation defect by applying the insulation defect detection system for magnet wire coating. In FIG. 18, a rotary electric machine is showed as an example of the electric machine 70.

This electric machine 70 can also be manufactured by a manufacturing method for an electric machine including a step of manufacturing the electric machine including the stator core 62, using this stator core 62 wound with the magnet wire 2 confirmed to have no insulation defect by applying the insulation defect detection system for magnet wire coating.

As described above, the insulation defect detection system and detection method for magnet wire coating according to Embodiment 7 is applied to the winding process for the stator which is an armature of the rotary electric machine or the linear motion machine as an example of an electric machine.

Therefore, the insulation defect detection system and detection method for magnet wire coating according to Embodiment 7 can detect an insulation defect without applying excessively high voltage to the entire magnet wire before winding, and can provide the stator which is an armature of the rotary electric machine or the linear motion machine using the magnet wire with improved reliability.

As described above, in the insulation defect detection system and detection method for magnet wire coating according to Embodiment 1 to Embodiment 7, in the case where, when the discharge signal is detected two or more times in the running path for the insulation defect detection for magnet wire coating, the feature amount is calculated from each discharge signal and the discharge signals can be determined to be coincident with or similar to each other from the result, an insulation defect in magnet wire coating is determined to have been detected. Thus, when the discharge signal is sensed only once, excessive voltage is not applied to the magnet wire to detect an insulation defect in magnet wire coating, thereby not resulting in damage.

Therefore, in the insulation defect detection system and detection method for magnet wire coating according to Embodiment 1 to Embodiment 7, the entirety of the magnet wire to be wound can be inspected with high accuracy, before the winding process.

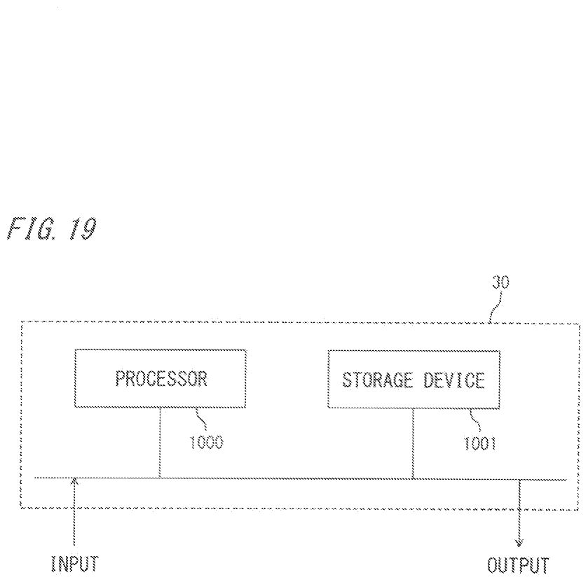

Here, one example of hardware of the evaluation device 30 in the insulation defect detection system for magnet wire coating is shown in FIG. 19. As shown in FIG. 19, the evaluation device 30 is composed of a processor 1000 and a storage device 1001. The storage device includes, although not shown, a volatile storage device such as a random access memory, and a con-volatile auxiliary storage device such as a flash memory.

Alternatively, the storage device may include an auxiliary storage device of a hard disk instead of a flash memory. The processor 1000 executes a program inputted from the storage device 1001. In this case, the program is inputted from the auxiliary storage device through the volatile storage device to the processor 1000. Further, the processor 1000 may output data such as a calculation result to the volatile storage device of the storage device 1001 or may save the data through the volatile storage device into the auxiliary storage device.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more or the embodiments of the disclosure.

It is therefore understood that numerous modifications which have not been exemplified can be devised without departing from the scope of the present disclosure. For example, at least one of the constituent parts may be modified, added, or eliminated. At least one of the constituent parts mentioned in at least one of the preferred embodiments may be selected and combined with the constituent parts mentioned in another preferred embodiment.

### DESCRIPTION OF THE REFERENCE CHARACTERS

1 running path
2 magnet wire
2A magnet wire conductor
2B magnet wire coating
3 feeding bobbin
4 winding bobbin
5 delivery machine
6 winding machine
7 turntable
10 AC power supply
11 first discharge sensing electrode
12 second discharge sensing electrode
13 first discharge detection device
14 second discharge detection device
15 third discharge sensing electrode
16 third discharge detection device
17 fourth discharge sensing electrode
18 fourth discharge detection device
20 reference signal generator
21 first charge eliminating electrode
22 second charge eliminating electrode
23 third charge eliminating electrode
24 fourth charge eliminating electrode
30 evaluation device
31 A/D converter
32 storage unit
33 calculation unit
34 measuring unit
35 comparison unit
36 image output unit
37 image display device
41 insulation defect
42 coupling capacitor
43 detection impedance
44 discharge detector
45 capacitance of normal portion in magnet wire coating
46 capacitance of insulation defect portion
47 capacitance of portion connected in series with the insulation defect portion
48 capacitance of coupling capacitor
51 guide block
52 guide hole on upstream side
53 guide hole on downstream side
59 groove
61 nozzle of winding
62 stator core
70 electric machine
100, 200, 300, 400, 500, 600, 700 insulation defect detection system for magnet wire coating
1000 processor
1001 storage device

1. An insulation defect detection method for magnet wire coating, for detecting a defect in the magnet wire coating, the method comprising:
a running step of causing a magnet wire to run at a constant speed in a line direction;
a first discharge detection step of detecting a discharge current caused by a first discharge as a fluctuation in AC voltage by applying the AC voltage to a first measurement point on the running magnet wire;
a second discharge detection step of detecting a discharge current caused by a second discharge as a fluctuation in the AC voltage by applying the AC voltage to a second measurement point on the magnet wire after the first discharge is detected;
a discharge storing step of storing the first discharge detected in the first discharge detection step and the second discharge detected in the second discharge detection step;
a time calculation step of calculating time taken for the magnet wire to move from the first measurement point to the second measurement point, from a running speed of the magnet wire and a distance between the first measurement point and the second measurement point;
a time measurement step of measuring the time taken for the magnet wire to move from the first measurement point to the second measurement point; and
a determination step of determining whether or not the magnet wire coating has a defect by comparing the first discharge with the second discharge.

2. The insulation defect detection method for magnet wire coating according to claim 1, wherein
in the determination step, a discharge signal of the first discharge is compared with a discharge signal of the second discharge detected at the second measurement point after the time taken to move to the second measurement point has passed since detection of the first discharge at the first measurement point, and
if a difference between the compared two discharge signals is in a predetermined range, the magnet wire coating is determined to have a defect.

3. The insulation defect detection method for magnet wire coating according to claim 2, wherein
the determination step includes a discharge feature amount calculation step of calculating a peak discharge electric-charge amount, a discharge duration time, or a total discharge electric-charge amount of the discharge signals of the first discharge and the second discharge,
determination is performed on the basis of one or a combination of two or more of feature amounts including the peak discharge electric-charge amount, the discharge duration time, and the total discharge electric-charge amount, and
if a difference between the feature amounts or a matching rate of the feature amounts is in a predetermined range, the magnet wire coating is determined to have a defect.

4. The insulation defect detection method for magnet wire coating according to claim 1, wherein
the time measurement step includes a magnet wire running sensing step of sensing that the magnet wire is running,
measurement of time taken for the magnet wire to move is continued only while the magnet wire is running, and
the measurement of the time taken for the magnet wire to move is stopped while the magnet wire is stopped.

5. The insulation defect detection method for magnet wire coating according to claim 1, further comprising
a reference signal transmission step of transmitting a reference signal having a reference discharge electric-charge amount, wherein
the reference signal is detected in advance in a first discharge sensing electrode at the first measurement point and a second discharge sensing electrode at the second measurement point, and
in the discharge storing step, a signal having the discharge electric-charge amount of the reference signal or lower is removed, with reference to the detected reference signal.

6. The insulation defect detection method for magnet wire coating according to claim 2, wherein
in the determination step, waveform smoothing processing is further performed to smooth a waveform of the detected discharge signal.

7. The insulation defect detection method for magnet wire coating according to claim 6, wherein
in the waveform smoothing processing, a moving average of the discharge signal is calculated.

8. The insulation defect detection method for magnet wire coating according to claim 1, sequentially comprising
third to Nth discharge detection steps of detecting discharge by applying the AC voltage to third to Nth measurement points on the magnet wire after the second discharge is detected, N being an integer of 3 or more, wherein
in the determination step, the discharge signals detected in the third to Nth discharge detection steps are additionally compared, and whether or not the magnet wire has a defect is determined.

9. An insulation defect detection system for magnet wire coating, for detecting a defect in the magnet wire coating, the system comprising:
a delivery circuitry and a winding circuitry that are respectively disposed in front and back of a running path of a magnet wire and cause the magnet wire to run at a constant speed in a line direction;
an AC power supply that generates AC voltage to be applied for detecting discharge from a defect in the magnet wire coating in the running path;
a first discharge sensing electrode and a second discharge sensing electrode that are respectively disposed at a first measurement point and a second measurement point to sense the discharge from a defect in the magnet wire coating;
a first discharge detection circuitry that detects a discharge current sensed by the first discharge sensing electrode as a fluctuation in the AC voltage, and a second discharge detection circuitry that detects a discharge current sensed by the second discharge sensing electrode as a fluctuation in the AC voltage; and
an evaluation circuitry including a comparison circuitry that determines whether or not the magnet wire coating has a defect, by comparing the discharge signal of the first discharge detected at the first measurement point with the discharge signal of the second discharge detected at the second measurement point.

10. An insulation defect detection system for magnet wire coating, for detecting a defect in the magnet wire coating, the system comprising:
a delivery circuitry and a winding circuitry that are respectively disposed in front and back of a running path of a magnet wire and cause the magnet wire to run at a constant speed in a line direction;
an AC power supply that generates AC voltage to be applied for detecting discharge from a defect in the magnet wire coating in the running path;
a first discharge sensing electrode and a second discharge sensing electrode that are respectively disposed at a first measurement point and a second measurement point to sense the discharge from a defect in the magnet wire coating;
a first discharge detection circuitry that detects a discharge signal sensed by the first discharge sensing electrode, and a second discharge detection circuitry that detects a discharge signal sensed by the second discharge sensing electrode; and
an evaluation circuitry including a comparison circuitry that determines whether or not the magnet wire coating has a defect, by comparing the discharge signal of the first discharge detected at the first measurement point with the discharge signal of the second discharge detected at the second measurement point, further comprising:
a discharge storage circuitry that stores the discharge signal detected by the first discharge detection circuitry and the discharge signal detected by the second discharge detection circuitry;
a time calculation circuitry that calculates time taken for the magnet wire to move from the first measurement point to the second measurement point, from a running speed of the magnet wire and a distance between the first measurement point and the second measurement point; and
a time measurement circuitry that measures the time taken for the magnet wire to move from the first measurement point to the second measurement point.

11. The insulation defect detection system for magnet wire coating according to claim 10, wherein
in the comparison circuitry,
a peak discharge electric-charge amount, a discharge duration time, or a total discharge electric-charge amount of each of the discharge signal of the first discharge and the discharge signal of the second discharge is calculated,
determination is performed on the basis of one or a combination of two or more of feature amounts including the peak discharge electric-charge amount, the discharge duration time, and the total discharge electric-charge amount, and
if a difference between the feature amounts or a ratio difference between the feature amounts is in a predetermined range, the magnet wire coating is determined to have a defect.

12. The insulation defect detection system for magnet wire coating according to claim 10, wherein
the time measuring circuitry receives a running signal indicating that the magnet wire is running, and continues measurement only while the magnet wire is running and stops the measurement while the magnet wire is stopped.

13. The insulation defect detection system for magnet wire coating according to claim 9, further comprising
charge eliminating electrodes that are respectively disposed at a position downstream of the first measurement point and upstream of the second measurement point, and at a position downstream of the second measurement point, and eliminate electric charge staying on an outer surface of the magnet wire, with AC voltage applied at the first measurement point and AC voltage applied at the second measurement point.

14. The insulation defect detection system for magnet wire coating according to claim 9, further comprising
a reference signal generator that transmits a reference signal having a reference discharge electric-charge amount, wherein
the reference signal is detected in the first discharge sensing electrode and the second discharge sensing electrode, and
in the first discharge detection circuitry and the second discharge detection circuitry, a signal having the discharge electric-charge amount of the reference signal or lower is removed, with reference to the detected reference signal.

15. The insulation defect detection system for magnet wire coating according to claim 9, further comprising
a guide block that guides the magnet wire in front and back of each of the first discharge sensing electrode and the second discharge sensing electrode.

16. The insulation defect detection system for magnet wire coating according to claim 15, wherein
the guide block is formed of a resin material having a cube shape, and
the guide block has a groove for storing each of the first discharge sensing electrode and the second discharge sensing electrode in the guide block, and each of the first discharge sensing electrode and the second discharge sensing electrode is stored in the groove,
the guide block has a through hole penetrating two faces opposite to each other across a circular face of each of the first discharge sensing electrode and the second discharge sensing electrode,
the groove has a center point coincident with a center point of each of the first discharge sensing electrode and the second discharge sensing electrode, and an inner diameter larger than an outer diameter of the magnet wire by about 10 to 100 μm.

17. The insulation defect detection system for magnet wire coating according to claim 16, wherein the resin material of the guide block is fluorinated resin.

18. The insulation defect detection system for magnet wire coating according to claim 9, wherein
the comparison circuitry further has a function of smoothing a waveform of each of the discharge signal detected by the first discharge detection circuitry and the discharge signal detected by the second discharge detection circuitry.

19. The insulation defect detection system for magnet wire coating according to claim 18, wherein a moving average of the discharge signal is calculated to smooth the waveform of the discharge signal.

20. The insulation defect detection system for magnet wire coating according to claim 9, further comprising
an image output circuitry and an image display circuitry for displaying an image of a latest discharge signal by which the magnet wire coating has been determined to have a defect, together with a cumulative number of times that the magnet wire coating has been determined to have a defect.

21. The insulation defect detection system for magnet wire coating according to claim 9, further comprising:
third to Nth discharge sensing electrodes respectively disposed at third to Nth measurement points downstream of the second discharge sensing electrode, N being an integer of 3 or more; and
third to Nth discharge detection circuitries that detect discharge signals sensed by the third to Nth discharge sensing electrodes, wherein
the comparison circuitry determines whether or not the magnet wire coating has the defect, by additionally comparing the discharge signals detected at the third to Nth measurement points.

22. The insulation defect detection system for magnet wire coating according to claim 9, wherein
the magnet wire after passing through the running path for detecting a defect in magnet wire coating is caused to run to a winding wire circuitry for winding the magnet wire around a core, and is wound around the core by a winding mechanism unit of the winding circuitry.

23. A manufacturing method for an electric machine, comprising a step of manufacturing the electric machine using the core wound with the magnet wire according to claim 22.

24. An electric machine comprising the core wound with the magnet wire according to claim 22.
